(19) United States
(12) Patent Application Publication
(10) Pub. No.: US 2009/0189660 A1
(43) Pub. Date: Jul. 30, 2009

(54) SEMICONDUCTOR DEVICE

(75) Inventor: Hiroshi SEKI, Suwa-shi (JP)

Correspondence Address: OLIFF & BERRIDGE, PLC, P.O. BOX 320850, ALEXANDRIA, VA, 22320-4850, US

(73) Assignee: SEIKO EPSON CORPORATION, Tokyo (JP)

(21) Appl. No.: 12/361,150

(22) Filed: Jan. 28, 2009

(30) Foreign Application Priority Data
Jan. 30, 2008 (JP) 2008-018473

(51) Int. Cl. H03L 7/00

(52) U.S. Cl. 327/161

(57) ABSTRACT

A semiconductor device includes an input circuit, an output circuit, and a test circuit that is adapted to evaluate delaying of a signal which is input to the input circuit to be output from the output circuit. The test circuit includes a first delay circuit for delaying a signal output from the input circuit, a second delay circuit which is configured of a plurality of serially connected gate circuits and is adapted to further delay a signal output from the first delay circuit, a through-path which is configured of a wiring pattern and is adapted to transmit the signal output from the first delay circuit, a selector that selects one of a signal output from the second delay circuit and a signal transmitted through the through-path according to a control signal to supply the selected signal to the output circuit, and a control signal generating circuit that generates the control signal according to the signal output from the input circuit so as to allow the selector to alternately select the signal output from the second delay circuit and the signal transmitted through the through-path.

### BACKGROUND

1. Technical Field

The present invention generally relates to a semiconductor device, in particular to one provided with a test circuit for measuring a delay time.

2. Related Art

In a semiconductor device such as an ASIC (Application Specific IC), layout designing is carried out such that a plurality of cells for realizing various kinds of logical circuits are combined to be arranged in a layout area, and then the cells are wired. In the layout designing of the semiconductor device, it is necessary to check whether or not the circuits adequately operate in consideration of delay times of the respective cells. A delay time by a circuit element such as a transistor and a delay time by a wiring pattern are input to calculation as the delay times.

For this reason, a library to be used in the layout designing of a semiconductor device is provided with a test circuit for measuring a delay time, and then the semiconductor device having built therein a test circuit is actually manufactured. Evaluation of delaying in the test circuit is carried out while measuring the delay time by using an LSI tester or the like.

FIG. 4 shows an example of a test circuit in a semiconductor device heretofore employed. While the test circuit is configured of a plurality of serially connected inverters, an input node A of the test circuit is connected to an input circuit and an output node X of the test circuit is connected to an output circuit.

In a case where the above test circuit is built in a semiconductor chip, a wiring length α between the input circuit and the input node A and a wiring length β between the output node X and the output circuit are differed from each other depending on the size of the semiconductor chip. Even when sizes of semiconductor chips are the same, if the circuit arrangements in the semiconductor chips are different from each other, the wiring lengths α and β are made to be differed from each other. In addition, in a case where the delay time of the test circuit is measured by using an LSI tester, even when an identical semiconductor chip is measured, the measured values are varied among LSI testers because of a difference in stray capacitances or parasitic resistances.

To solve the above problem, a semiconductor device and a testing method therefore capable of evaluating the delaying without being affected by the chip size or the measuring device are disclosed in Japanese patent No. 3487281 (pages 1 and 3, and FIG. 3) which is an example of related art. As in FIG. 3 of the above patent document, the semiconductor device includes a first delay path outputting an input signal from an input I/O cell 200 to an output I/O cell 214 through a first delay circuit 150 and a given wiring layer, a through-path 210 outputting the input signal from the input I/O cell 200 to the output I/O cell 214 by passing it not through the delay circuit but through the given wiring layer, and a delay path switching circuit 152 for switching between the first delay path and the through-path to select one of them, through which the signal is output to the output I/O cell 214.

In the above patent document, as the delay time without using the delay circuit is subtracted from the delay time using the delay circuit, influence by the wiring lengths α and β shown in FIG. 4 is canceled and also influence by the size of the chip, an allocated position of a delay element, and a stray capacitance or a parasitic resistance of an LSI tester is canceled, thereby it is possible to achieve highly accurate measuring of a delay time. However, it is necessary to input a control signal (measurement switching signal) for switching between the delay path and the through-path from an external device so that a problem arises that the number of pins (terminals) for testing is increased.

### SUMMARY

An advantage of the present invention is to provide a semiconductor device capable of highly accurately measuring a delay time without providing a terminal for inputting a control signal from an external device.

A semiconductor device of the invention includes an input circuit, an output circuit, and a test circuit that is adapted to evaluate delaying of a signal which is input to the input circuit to be output from the output circuit. The test circuit includes a first delay circuit for delaying a signal output from the input circuit, a second delay circuit which is configured of a plurality of serially connected gate circuits and is adapted to further delay a signal output from the first delay circuit, a through-path which is configured of a wiring pattern and is adapted to transmit the signal output from the first delay circuit, a selector that selects one of a signal output from the second delay circuit and a signal transmitted through the through-path according to a control signal to supply the selected signal to the output circuit, and a control signal generating circuit that generates the control signal according to the signal output from the input circuit so as to allow the selector to alternately select the signal output from the second delay circuit and the signal transmitted through the through-path.

Here, the first delay circuit may be configured of a plurality of serially connected gate circuits. In addition, the selector may be configured to select the signal output from the second delay circuit when the control signal is in a first level and to select the signal transmitted through the through-path when the control signal is in a second level.

Further in addition, the control signal generating circuit may include a D flip-flop having a clock signal input terminal for receiving the signal output from the input circuit and an output terminal for outputting the control signal, an inverted output terminal, and a data input terminal. A signal output from the inverted output terminal is input to the data input terminal, and the level of the control signal is inverted in synchronization with a rising edge of the signal output from the input circuit.

### BRIEF DESCRIPTION OF THE DRAWINGS

The invention will be described with reference to the accompanying drawings, wherein like numbers reference like elements.

FIG. 1 is a structural view showing a part of a semiconductor device according to a first embodiment of the invention.

FIG. 2 is a circuit diagram illustrating a structural example of a control signal generating circuit shown in FIG. 1.

FIG. 3 is a timing chart illustrating a waveform at each section of a test circuit shown in FIG. 1.

FIG. 4 is a circuit diagram showing a test circuit in a semiconductor device of an example of the related art.

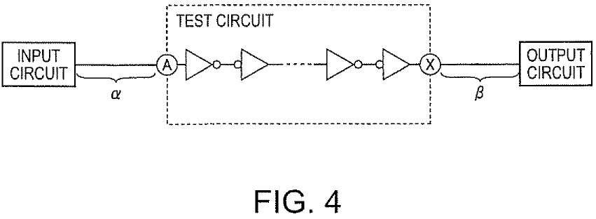

### DESCRIPTION OF EXEMPLARY EMBODIMENTS

The preferred embodiments of the semiconductor device of the invention will be described with reference to the accompanying drawings.

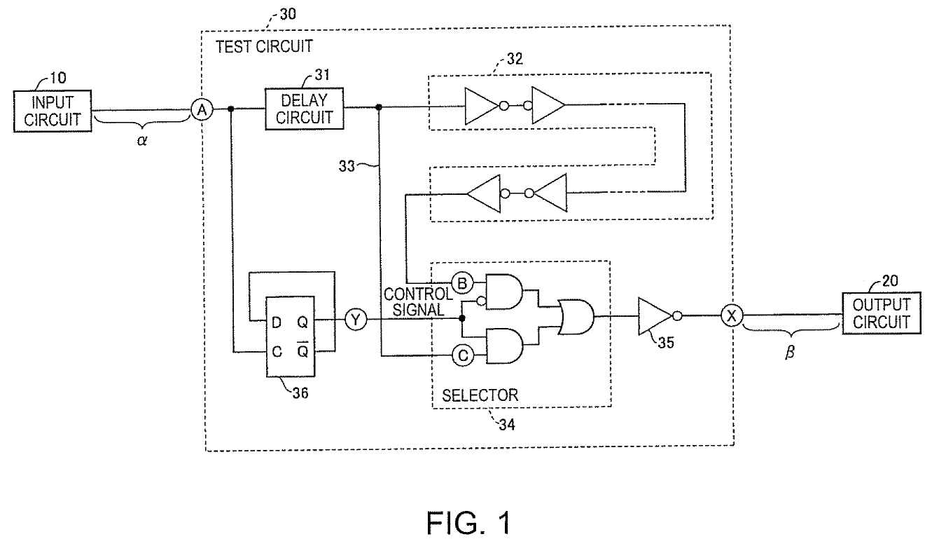

FIG. 1 is a structural view showing a part of a semiconductor device according to a first embodiment of the invention. As shown in FIG. 1, a test circuit 30 for measuring a delay time is connected between an input circuit 10 and an output circuit 20 in the semiconductor device. A circuit structure and a layout of the test circuit 30 is installed in a library to be used in layout designing of a semiconductor device. In a case where the semiconductor device including the test circuit 30 is actually manufactured, a delay time on the test circuit 30 is measured by using an LSI tester or the like to evaluate delaying.

The input circuit 10 includes an input pad and an I/O cell and the output circuit 20 includes an I/O cell and an output pad. An input node A of the test circuit 30 is connected to the input circuit 10 and an output node X of the test circuit 30 is connected to the output circuit 20. A wiring length between the input circuit 10 and the input node A is represented by “α”, and a wiring length between the output node X and the output circuit 20 is represented by “β”. The wiring lengths α and β are respectively varied depending on a size of a semiconductor chip. Even when the sizes of the semiconductor chips are the same, the wiring lengths α and β are respectively varied, if the circuit arrangements in the semiconductor chips are different from each other.

The test circuit 30 is configured of a delay circuit 31 for timing adjustment, a delay circuit 32 for delay time measurement, a through-path 33, a selector 34, an inverter 35, for a buffer, and a control signal generating circuit 36.

The delay circuit 31 delays a signal output from the input circuit 10, and the delay circuit 32 further delays a signal output from the delay circuit 31. Each of the delay circuits 31 and 32 is constituted such that, for example, a plurality of gate circuits (logical circuits) are connected in series. In this embodiment, the delay circuit 31 is formed of serially connected four hundreds inverters and its delay time is approximately 10 ns. The delay circuit 32 is formed of serially connected one thousand inverters and its delay time is approximately 20 ns. In the delay circuit 32, the plurality of gate circuits are laid out in a plurality of rows (two rows in FIG. 1) by turning them so that an input node and an output node of the delay circuit 32 can be brought into close proximity to each other.

Here, a path in which a signal output from the delay circuit 31 is transmitted to a node B of the selector 34 through the delay circuit 32, is called as “delay path”. The through-path 33 is configured of a wiring pattern and allows a signal output from the delay circuit 31 to be transmitted to a node C of the selector 34.

The selector 34 is adapted to select one of the signal output from the delay circuit 32 and the signal transmitted through the through-path 33 according to the control signal and to supply it to the output circuit 20 through the inverter 35. In this embodiment, the selector 34 is configured of two AND gates (input of one of the AND gates is a negative logic) and one OR gate. The selector 34 selects the signal output from the delay circuit 32 when the control signal is in a low level and selects the signal transmitted from the through-path 33 when the control signal is in a high level.

The control signal generating circuit 36 generates the control signal according to a signal output from the input circuit 10 to supply it to the selector 34 through a node Y so as to allow the selector 34 to select them alternately. In this embodiment, the control signal generating circuit 36 is configured of a D flip-flop. The D flip-flop has a clock signal input terminal C for receiving the signal from the input circuit 10 and an output terminal Q for outputting the control signal. A signal output from an inverted output terminal Q-bar is input to a data input terminal D, and the level of the control signal is inverted in synchronization with a rising edge of the signal output from the input circuit 10.

Here, while the control signal generating circuit 36 generates the control signal according to the signal output from the input circuit 10, the signal to be input to the delay circuit 32 and the through-path 33 is delayed by the delay circuit 31, so that the selection of the signal is carried out by the selector 34 before the signal is input to the selector 34 from the delay circuit 32 or through-path 33.

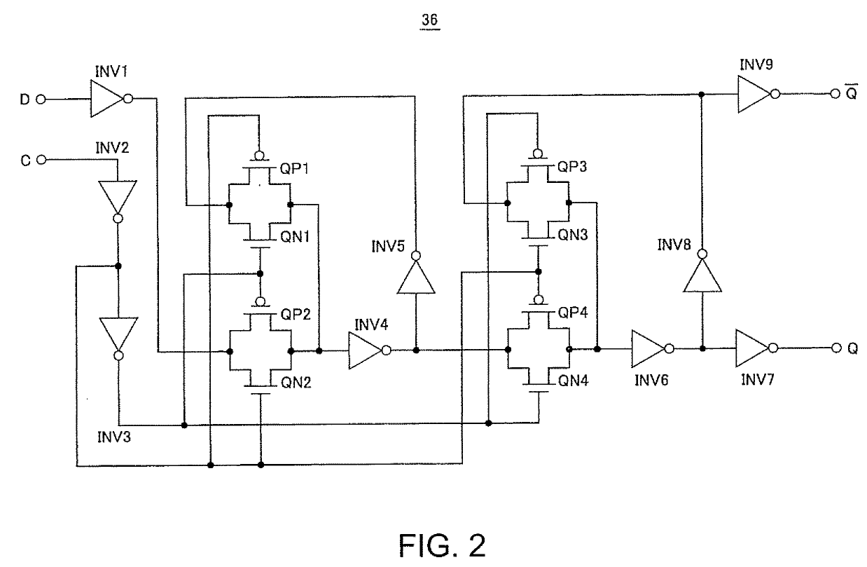

FIG. 2 is a circuit diagram illustrating a structural example of the control signal generating circuit shown in FIG. 1. As shown in FIG. 2, the control signal generating circuit (D flip-flop) 36 includes an inverter INV1 to which the signal from the data input terminal D is input, an inverter INV2 to which the signal from the clock signal input terminal C is input, an inverter INV3 for inverting a level of an output signal of the inverter INV2, a first analogue switch configured of a P channel MOS transistor QP1 and an N channel MOS transistor QN1, a second analogue switch configured of a P channel MOS transistor QP2 and an N channel MOS transistor QN2, an inverter INV4 to which a signal from the first or second analogue switch is input, and an inverter INV5 for inverting a level of an output signal of the inverter INV4.

An output signal of the inverter INV5 is input to the first analogue switch and an output signal of the inverter INV1 is input to the second analogue switch. The first and second analogue switches alternately turn on or off according to the output signals of the inverter INV2 and the INV3, respectively.

The control signal generating circuit (D flip-flop) 36 further includes a third analogue switch configured of a P channel MOS transistor QP3 and an N channel MOS transistor QN3, a fourth analogue switch configured of a P channel MOS transistor QP4 and an N channel MOS transistor QN4, an inverter INV6 to which a signal from the third or fourth analogue switch is input, inverters INV7 and INV8 for respectively inverting a level of an output signal of the inverter INV6, and an inverter INV9 for inverting a level of an output signal of the inverter INV8.

The output signal of the inverter INV8 is input to the third analogue switch and the output signal of the inverter INV4 is input to the fourth analogue switch. The third and fourth analogue switches alternately turn on or off according to the output signals of the inverters INV2 and INV3, respectively.

With the above configuration, when a signal input from the clock signal input terminal C rises from a low level to a high level, the first analogue switch turns on and the second analogue switch turns off so that a signal input to the data input terminal D is held at the output signal of the inverter INV4. In addition, as the third analogue switch turns off and the fourth analogue switch turns on, the output signal of the inverter INV4 is output from the output terminal Q.

On the other hand, when a signal input from the clock signal input terminal C changes from a high level to a low level, the first analogue switch turns off and the second analogue switch turns on, and then a signal input to the data input terminal D is output from the inverter INV4. In addition, as the third analogue switch turns on and the fourth analogue switch turns off at the same time, the signal of the output terminal is maintained as it is. A signal with an inverted level of the output terminal Q is output from an inverted output terminal Q-bar.

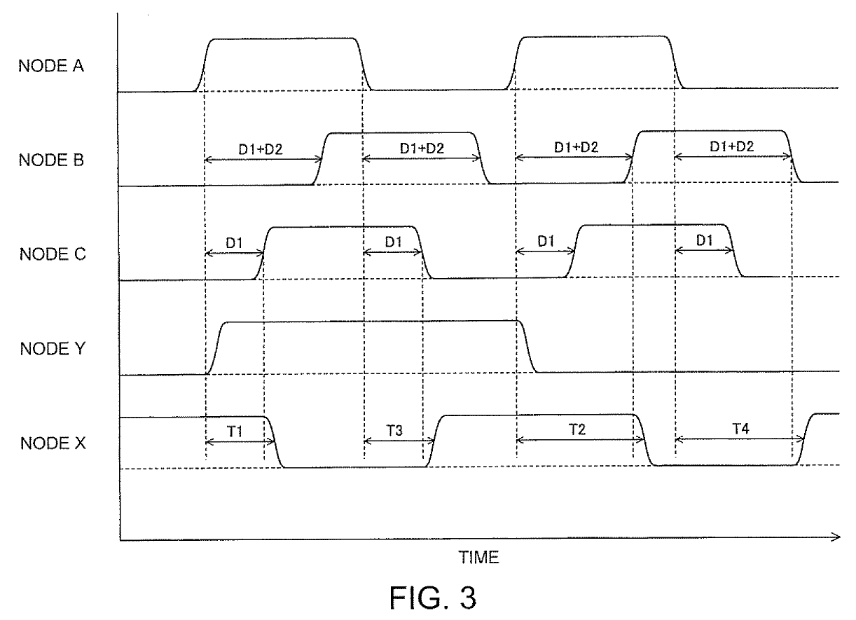

Next, an operation of the test circuit shown in FIG. 1 is described below. FIG. 3 is a timing chart showing a waveform of each section of the test circuit shown in FIG. 1. In FIG. 3, waveforms on the nodes A to D and X shown in FIG. 1 are illustrated. When a positive pulse having a prescribed width is applied to the input node A of the test circuit 30, a pulse delayed by a time D1 by the delay circuit 31 is transmitted to the node C, a pulse delayed by a delay time (D1+D2) by the delay circuits 31 and 32 is transmitted to the node B.

When an initial value of the control signal on the output terminal Q of the control signal generating circuit (D flip-flop) 36 is in a low level, the control signal on the node Y is shifted from a low level to a high level in synchronization with a rising edge of the first pulse on the input node A of the test circuit 30, and then the selector 34 selects the through-path 33. As a result, a negative pulse passing through the through-path 33 to the inverter 35 is transmitted to the output node X of the test circuit 30, and then it is possible to measure a delay time T1 till the falling edge of the negative pulse on the output node X from a rising edge of the first pulse on the input node A of the test circuit 30 as a reference.

In addition, even when a state of the input node A of the test circuit 30 is shifted from a high level to a low level, the selector 34 maintained the selection of the through-path 33, and then it is possible to measure a delay time T3 till a rising edge of the negative pulse on the output node X from a falling edge of the first pulse on the input node A of the test circuit 30 as a reference.

Next, the control signal on the node Y is shifted from a high level to a low level in synchronization with a rising edge of the second pulse on the input node A of the test circuit 30, and then the selector 34 selects the delay path. As a result, a negative pulse passing through the delay-path to the inverter 35 is transmitted to the output node X of the test circuit 30, and then it is possible to measure a delay time T2 till the falling edge of the negative pulse on the output node X from a rising edge of the second pulse on the input node A of the test circuit 30 as a reference.

In addition, even when the state of the input node A of the test circuit 30 is shifted from the high level to the low level, the selector 34 holds a state of selecting the delay path, and then it is possible to measure a delay time T4 till the rising edge of the negative pulse on the output node X from the falling edge of the second pulse on the input node A of the test circuit 30 as a reference.

On the basis of the above results, by computing a time difference |T2−T1 | or |T4−T3| a delay time by the delay circuit 32 can be obtained. Consequently, influence by the wiring lengths α and β, or influence by the stray capacitance or parasitic resistance of the LSI tester can be eliminated, and then the measuring of the delay time in the test circuit 30 can be carried out.

In the above, a case where the initial value of the control signal on the output terminal Q of the control signal generating circuit (D flip-flop) 36 is in the low level, is described. However, when the initial value of the control signal is in the high level, the control signal on the node Y is shifted from the high level to the low level in synchronization with the rising edge of the first pulse on the input node A of the test circuit 30, and then the selector 34 selects the delay-path.

As a result, a negative pulse passing through the delay-path to the inverter 35 is transmitted to the output node X of the test circuit 30. At that time, the delay time T1 till the falling edge of the negative pulse on the output node X from the rising edge of the first pulse on the input node A of the test circuit 30 as a reference, is measured, and the delay time T3 till the rising edge of the negative pulse on the output node X from the falling edge of the first pulse on the input node A of the test circuit 30 as a reference, is measured.

Next, the control signal on the node Y is shifted from the level to the high level in synchronization with the rising edge of the second pulse on the input node A of the test circuit 30, and then the selector 34 selects the through-path 33. As a result, the negative pulse passing through the through-path 33 to the inverter 35 is transmitted to the output node X of the test circuit 30.

At that time, the delay time T2 till the falling edge of the negative pulse on the output node X from the rising edge of the second pulse on the input node A of the test circuit 30 as a reference, is measured, and the delay time T4 till the rising edge of the negative pulse on the output node X from the falling edge of the second pulse on the input node A of the test circuit 30 as a reference, is measured. Accordingly, similarly as in the above, the delay time by the delay circuit 32 can be obtained by computing the time difference |T2−T1| or |T4−T3|.

According to the invention, since the control signal is generated according to the signal output from the input circuit so that the selector alternately selects the signal output from the second delay circuit and the signal transmitted through the through-path, it is possible to provide the semiconductor device capable of accurately measuring a delay time without providing a terminal for receiving a control signal from an external device.

The invention can be used in a semiconductor device provided with a test circuit for measuring a delay time.

What is claimed is:

1. A semiconductor device comprising:
an input circuit;
an output circuit; and
a test circuit that is adapted to evaluate delaying of a signal which is input to the input circuit to be output from the output circuit, wherein the test circuit includes,
a first delay circuit for delaying a signal output from the input circuit,
a second delay circuit which is configured of a plurality of serially connected gate circuits and is adapted to further delay a signal output from the first delay circuit,
a through-path which is configured of a wiring pattern and is adapted to transmit the signal output from the first delay circuit,
a selector that selects one of a signal output from the second delay circuit and a signal transmitted through the through-path according to a control signal to supply the selected signal to the output circuit, and
a control signal generating circuit that generates the control signal according to the signal output from the input circuit so as to allow the selector to alternately select the signal output from the second delay circuit and the signal transmitted through the through-path.

2. The semiconductor device according to claim 1, wherein the first delay circuit is configured of a plurality of serially connected gate circuits.

3. The semiconductor device according to claim 1, wherein the selector selects the signal output from the second delay circuit when the control signal is in a first level and selects the signal transmitted through the through-path when the control signal is in a second level.

4. The semiconductor device according to claim 1, wherein the control signal generating circuit includes a D flip-flop having a clock signal input terminal for receiving the signal output from the input circuit and an output terminal for outputting the control signal, an inverted output terminal, and a data input terminal, and a signal output from the inverted output terminal is input to the data input terminal, and a level of the control signal is inverted in synchronization with a rising edge of the signal output from the input circuit.
